(19) United States
(12) Patent Application Publication
(10) Pub. No.: US 2017/0164461 A1
(43) Pub. Date: Jun. 8, 2017

(54) CONDUCTIVE FLEXIBLE AND STRETCHABLE ENCAPSULATION METHOD AND APPARATUS

(71) Applicant: Intel Corporation, Santa Clara, CA (US)

(72) Inventors: Braxton Lathrop, Lake Oswego, OR (US); Sasha Oster, Chandler, AZ (US); Aleksandar Aleksov, Chandler, AZ (US); Nadine L. Dabby, Palo Alto, CA (US)

(21) Appl. No.: 14/962,692

(22) Filed: Dec. 8, 2015

(51) Int. Cl. H05K 1/02; H05K 1/09; H05K 3/12; H05K 1/03

(52) U.S. Cl. CPC H05K 1/028; H05K 1/0283; H05K 1/0346; H05K 1/0393; H05K 1/092; H05K 3/12; H05K 2201/0129; H05K 2201/0133

(57) ABSTRACT

Apparatus and methods are provided for flexible, stretchable, wearable electronics. In an example, an apparatus for providing flexible and stretchable conductors can include a first elastomer layer, conductive ink applied to the first elastomer layer, and an adhesive layer, in cooperation with the first elastomer layer, configured to encapsulate the conductive ink, the adhesive layer further configured to allow the apparatus to be attached to a second apparatus.

### TECHNICAL FIELD

The disclosure herein relates generally to wearable electronics and more particularly to flexible and stretchable, wearable electronics.

### BACKGROUND

Electronics continue to be developed that are smaller yet more powerful computationally and functionally. Opportunities and challenges continue to arise that push the creative enterprise of electronic designers to provide small powerful electronic products that provide desired user functionality in a convenient package. Wearable electronics have been developed yet have failed to capture widespread use because they are physically rigid, bulky, or lack computational or functional capabilities.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 illustrates generally an example flexible and stretchable portion of an electronic trace for a wearable electronic circuit.

FIGS. 2A-2E illustrate generally the incremental structural arrangement of the circuit during fabrication.

FIG. 3 illustrates generally a flowchart of the example method for fabricating a flexible and stretchable circuit portion.

FIG. 4 illustrates generally an example circuit portion 400 attached to a garment 404.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

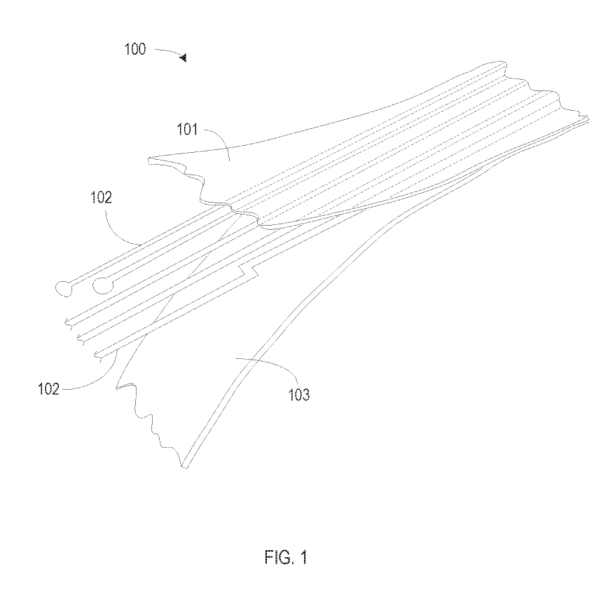

FIG. 1 illustrates generally an example flexible and stretchable portion 100 of an electronic trace for a wearable electronic circuit. In certain examples, the portion 100 can include a first layer 101, conductive traces 102, and a second layer 103. In certain examples, the first layer 101 can include an elastomer. In certain examples, the second layer can include an elastomer. In some examples, the second layer 103 can include an adhesive layer for attaching the electronic circuit to a textile or a garment. In some examples, the second layer 103 can be used to couple the electronic circuit to a user's skin. In certain examples, the elastomers referred to above with respect to the first layer 101 or the second layer 103 can include a thermoplastic elastomer, for example thermoplastic polyurethane. Thermoplastic elastomers can allow the circuit to be stretched and then when the stretching force is released, return to original length. In certain examples, the conductive traces 102 can be applied to either the first layer 101 or the second layer 103 via a printing operation using conductive ink, such as but not limited to, silver inks and pastes. Certain conductive inks can be cured after application to the respective layer 101, 103. In some examples, the ink can include function inks such as carbon ink for temperature sensing. In some examples, the ink can include patterned copper or other conductive metal.

In some examples, after application of the conductive traces 102 to the first layer 101, for example, the second layer 103 can be applied and can encapsulate the conductive traces 102. In certain examples, the encapsulation can provide waterproof protection of the traces. In some examples, an adhesive layer can be used to apply the circuit portion 100 to a garment. In some examples, the circuit portion 100 can be applied to a garment in the same fashion as seam tape is applied to a garment. Consequently, existing methods in the garment industry can be used to apply and create wearable electronics that include flexible and stretchable circuits such as the circuit portion 100 of FIG. 1. In certain examples, the portion 100 can be applied to a seam of a garment to seal the seam or to waterproof the seam, as well as to provide interconnection to one or more circuit components of a wearable circuit including the portion 100. In certain examples, the encapsulation material 101, 103 can include vias or openings filled with conductive material to allow connection to the encapsulated traces 102.

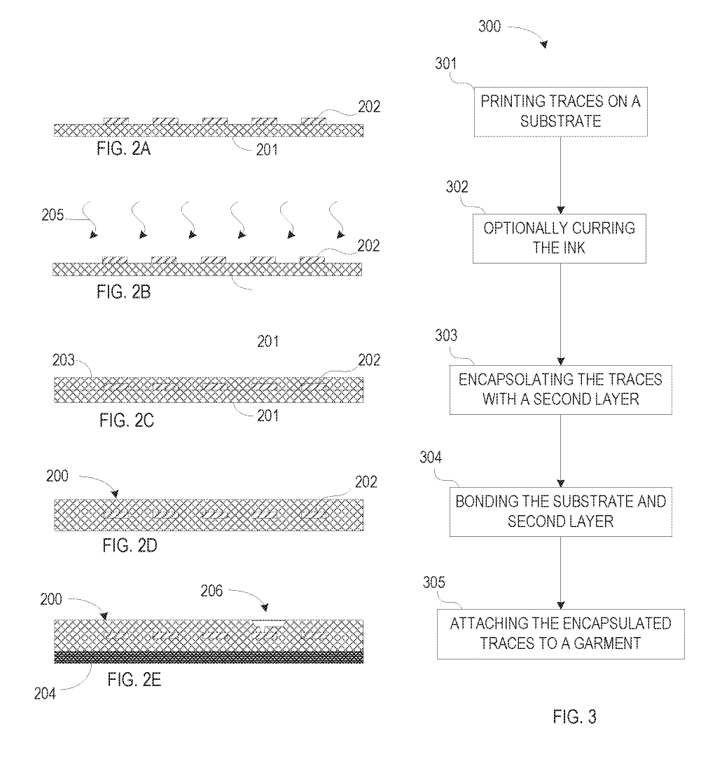

FIGS. 2A-2E and FIG. 3 illustrate generally an example method 300 for making a flexible and stretchable wearable circuit portion for wearable electronics. FIGS. 2A-2E illustrate generally the incremental structural arrangement of the circuit during the method 300. FIG. 3 illustrates generally a flowchart of the example method 300. At 301 (FIG. 2A), conductive traces 202 can be applied to a first layer 201 or substrate. In certain examples, the first layer 201 can include an elastomer. In some examples, the first layer can include an adhesive layer for attaching the finished product to a garment or to a user's skin. In certain examples, the conductive traces 102, can be applied by printing conductive ink on to the first layer 201. In some examples, the conductive ink can be printed using an ink-jet printer. In some examples, the conductive ink can be applied using gravure printing. In some examples, the conductive ink can be applied using screen print techniques. It is understood that other types of printing or patterning can be used to apply the conductive traces 202 without departing from the scope of the present subject matter. At 302 (FIG. 2B), as an option, the conductive traces can be cured, for example using some form of radiated energy 205 such as heat or ultraviolet light.

At 303 (FIG. 2C), a second layer 203 can be applied to the conductive traces 202 and the first layer 201 to encapsulate the conductive traces 202. In certain examples, the second layer 203 can be laminated to the first layer 201. In certain example, the second layer 203 can include an elastomer, such as a thermoplastic elastomer. In some examples, the second layer 203 can include an adhesive layer for attaching the finished product to a garment or to a user's skin. At 304 (FIG. 2D), the first and second layers 201, 203 can be bonded together to further encapsulate the conductive traces 202. In certain examples, bonding the layers 201, 203 can include heating the layers and pressing the layers together to form a flexible and stretchable circuit portion 200.

At 305 (FIG. 2E), the flexible and stretchable circuit portion 200 can be attached to a garment 204 or to a user's skin. In certain examples, a circuit including the circuit portion 200 can include a processor circuit and input and output devices to provide the garment wearer or the user with an interactive, wearable electronic device. In certain examples, vias or openings 206 can be made through the encapsulation material. In some examples, the vias or openings 206 can be filled with conductive material to allow external connection to the encapsulated traces 102. Such connection can be used to provide electrical connection of a trace to an external circuit or to a material such as a user's skin. In some examples, a punch or a die and punch apparatus can be used to create the vias or openings. In some examples, the vias or openings can be created using a laser cutter.

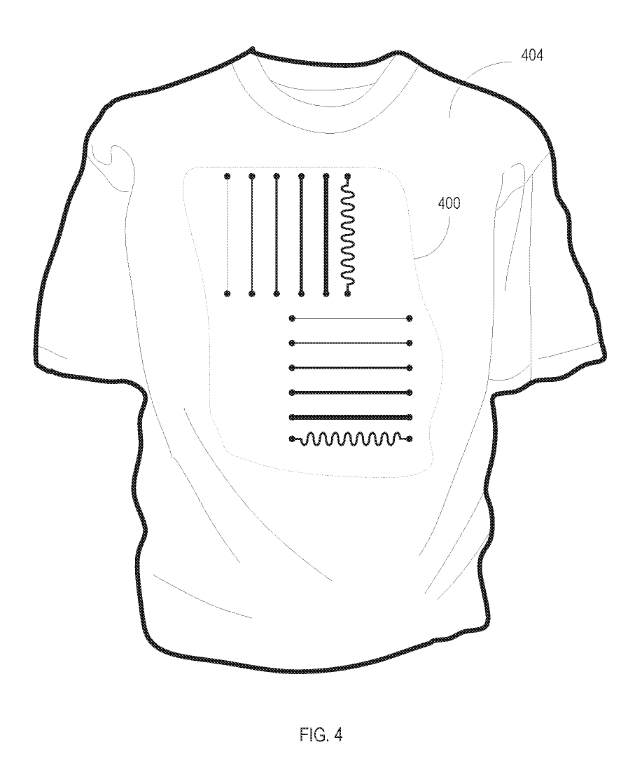

FIG. 4 illustrates generally an example circuit portion 400 attached to a garment 404. In certain examples, a flexible, stretchable, wearable circuit or circuit patch, can include the circuit portion 400 and other circuit components such as processing logic, memory, input and output devices, or communication devices. In certain examples, the circuit portion 400 can interconnect one or more of the other circuit components. In certain examples, the other circuit components that can also be attached to the garment 404 or attached to a user's skin and in combination can provide a wearable, interactive electronic device that includes flexible and stretchable circuit components. In certain examples, the circuit patch including the circuit portion 400 can be very thin, for example, on the order of light weight paper or cellophane. In certain examples, combining flexible ink with flexible adhesives and various elastomers can provide an easily used solution for the manufacture of smart garments without requiring large investments of capital or process changes to existing textile industry production flows. In addition, the flexible ink process can match the flexible nature of the substrate material and provide a solution for stretchable electronic garments. This process is also very amenable to the roll-to-roll or web based fabrication processes for high-volume manufacturing. In addition, although the above example apply to wearable application, the technology can also be applied to other fabric or textile based applications, for example, but not limited to, flags, tents, sleeping bags, bed or furniture coverings including sheets, spreads, pillows, etc.

### ADDITIONAL EXAMPLES AND NOTES

In Example 1, a method can include printing circuit traces on a elastomer substrate using conductive ink and encapsulating the circuit traces using an adhesive layer coupled to the elastomer substrate.

In Example 2, the printing of Example 1 optionally includes printing the circuit traces on a thermoplastic elastomer substrate using the conductive ink.

In Example 3, the printing of any one or more of Examples 1-2 optionally includes printing the circuit traces on a thermoplastic polyurethane substrate using the conductive ink.

In Example 4, the encapsulating includes of any one or more of Examples 1-3 optionally include encapsulating the circuit traces using seam tape coupled to the elastomeric substrate.

In Example 5, the adhesive layer of any one or more of Examples 1-4 optionally includes a thermoplastic elastomer.

In Example 6, the thermoplastic elastomer of any one or more of Examples 1-5 optionally includes thermoplastic polyurethane.

In Example 7, the encapsulating of any one or more of Examples 1-6 optionally includes hot pressing the elastomer substrate with the adhesive layer.

In Example 8, the printing includes of any one or more of Examples 1-7 optionally curing the conductive ink.

In Example 9, the method of any one or more of Examples 1-8 optionally includes attaching the adhesive layer to a garment.

In Example 10, the attaching of any one or more of Examples 1-9 optionally includes hot pressing the adhesive layer to the garment.

In Example 11, the method of any one or more of Examples 1-10 optionally includes attaching the adhesive layer to the body of a user.

In Example 12, an apparatus for providing flexible and stretchable conductors can include a first elastomer layer, conductive ink applied to the first elastomer layer, and an adhesive layer, in cooperation with the first elastomer layer, configured to encapsulate the conductive ink, the adhesive layer configured to allow the apparatus to be attached to a second apparatus.

In Example 13, the first elastomer layer of any one or more of Examples 1-12 optionally includes a thermoplastic elastomer.

In Example 14, the thermoplastic elastomer of any one or more of Examples 1-13 optionally includes thermoplastic polyurethane.

In Example 15, the adhesive layer of any one or more of Examples 1-14 optionally includes a thermoplastic elastomer.

In Example 16, the thermoplastic elastomer of any one or more of Examples 1-15 optionally includes thermoplastic polyurethane.

In Example 17, the adhesive layer of any one or more of Examples 1-16 optionally is configured to allow the apparatus to be attached to a garment.

In Example 18, the adhesive layer of any one or more of Examples 1-17 optionally is configured to allow the apparatus to be attached to a user's skin.

In Example 19, the adhesive layer of any one or more of Examples 1-18 optionally is configured to seal a seam of a garment.

In Example 20, the adhesive layer of any one or more of Examples 1-19 optionally is configured to waterproof a seam of a garment.

In Example 21, the conductive ink of any one or more of examples 1-20 can include silver ink.

Each of these non-limiting examples can stand on its own, or can be combined with one or more of the other examples in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

1. An apparatus for providing flexible and stretchable conductors, the apparatus comprising:
a first elastomer layer;
conductive ink applied to the first elastomer layer; and
an adhesive layer, in cooperation with the first elastomer layer, configured to encapsulate the conductive ink, the adhesive layer configured to allow the apparatus to be attached to a garment and to waterproof a seam of the garment.

2. The apparatus of claim 1, wherein the first elastomer layer includes a thermoplastic elastomer.

3. The apparatus of claim 2, wherein the thermoplastic elastomer includes thermoplastic polyurethane.

4. The apparatus of claim 1, wherein the adhesive layer includes a thermoplastic elastomer.

5. The apparatus of claim 4, wherein the thermoplastic elastomer includes thermoplastic polyurethane.

6-20. (canceled)
